(19) United States
(12) Patent Application Publication
(10) Pub. No.: US 2026/0052743 A1
(43) Pub. Date: Feb. 19, 2026

(54) SEMICONDUCTOR DEVICE AND MANUFACTURING METHOD THEREOF

(71) Applicant: UNITED MICROELECTRONICS CORP., Hsin-Chu City (TW)

(72) Inventors: Rudy Octavius Sihombing, Batam (ID); Jinyu Liao, Singapore (SG); Abhishek Attri, Ambala City (IN); Yihang Lin, Singapore (SG); Xiaoyuan Zhi, Singapore (SG); Su Xing, Singapore (SG); Purakh Raj Verma, Singapore (SG)

(73) Assignee: UNITED MICROELECTRONICS CORP, Hsin-Chu City (TW)

(21) Appl. No.: 18/889,406

(22) Filed: Sep. 19, 2024

(30) Foreign Application Priority Data
Aug. 13, 2024 (TW) 113130289

(51) Int. Cl. H01L 29/08

(52) U.S. Cl. CPC H10D 62/151

(57) ABSTRACT

A semiconductor device includes a buried insulation layer, a semiconductor layer, an isolation structure, a recess, a first gate structure, and a first source/drain doped region. The semiconductor layer and the isolation structure are disposed on the buried insulation layer, and the semiconductor layer includes a first active region surrounded by the isolation structure. The recess is disposed in the first active region, and the first active region includes a first portion and a second portion. The first portion is located under the recess, the second portion is connected with the first portion, and a thickness of the second portion is greater than that of the first portion. The first gate structure is disposed on the first portion, the first source/drain doped region is disposed in the first active region, and the first source/drain doped region is partly disposed in the second portion and partly disposed in the first portion.

### BACKGROUND OF THE INVENTION

### 1. Field of the Invention

The present invention relates to a semiconductor device and a manufacturing method thereof, and more particularly, to a semiconductor device including an active region with different thicknesses and a manufacturing method thereof.

### 2. Description of the Prior Art

In the semiconductor manufacturing related field, the size of functional devices in the integrated circuits becomes smaller continuously for enhancing the performance of the chip. However, as the density of the functional devices increased, the influence of many electrical properties on the device operation performance becomes more obvious, and that will hinder the development of scaling down. For example, in the radiofrequency switch device, the on resistance (Rₒₙ) and the off capacitance (C_{off}) are important indexes. The consumption ratio of signals passing through the switch device at the on-stage is rated to the on resistance, and the leakage ratio of signals at the off-stage is related to the off capacitance. The figure of merit (FOM) obtained by multiplying the on resistance and the off capacitance may be regarded as a performance index of the radiofrequency switch device. How to improve the figure of merit and reduce other negative influences through structural design and/or process design is an ongoing research direction for people in related fields.

### SUMMARY OF THE INVENTION

A semiconductor device and a manufacturing method thereof are provided in the present invention. An active region is partially thinned by forming a recess in the active region for improving operation performance of the semiconductor device.

According to an embodiment of the present invention, a semiconductor device is provided. The semiconductor device includes a buried insulation layer, a semiconductor layer, an isolation structure, a recess, a first gate structure, and a first source/drain doped region. The semiconductor layer and the isolation structure are disposed on the buried insulation layer. The semiconductor layer includes a first active region surrounded by the isolation structure. The recess is disposed in the first active region, and the first active region includes a first portion and a second portion. The first portion is located under the recess, the second portion is connected with the first portion, and a thickness of the second portion is greater than a thickness of the first portion. The first gate structure is disposed on the first portion, the first source/drain doped region is disposed in the first active region, and the first source/drain doped region is partly disposed in the second portion and partly disposed in the first portion.

According to an embodiment of the present invention, a manufacturing method of a semiconductor device is provided. The manufacturing method includes the following steps. A buried insulation layer is provided, a semiconductor layer and an isolation structure are formed on the buried insulation layer, and the semiconductor layer includes a first active region surrounded by the isolation structure. A recess is formed in the first active region, and the first active region includes a first portion and a second portion after the recess is formed. The first portion is located under the recess, the second portion is connected with the first portion, and a thickness of the second portion is greater than a thickness of the first portion. A first gate structure is formed on the first portion, a first source/drain doped region is formed in the first active region, and the first source/drain doped region is partly formed in the second portion and partly formed in the first portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor device according to a first embodiment of the present invention.

FIGS. 2-8 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 8 is a schematic drawing in a step subsequent to FIG. 7.

FIG. 9 is a schematic drawing illustrating a manufacturing method of a semiconductor device according to another embodiment of the present invention.

FIG. 10 is a schematic drawing illustrating a semiconductor device according to a second embodiment of the present invention.

FIG. 11 is a schematic drawing illustrating layout design of a semiconductor device according to a third embodiment of the present invention.

FIG. 12 is a schematic drawing illustrating a cross-sectional view of the semiconductor device according to the third embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

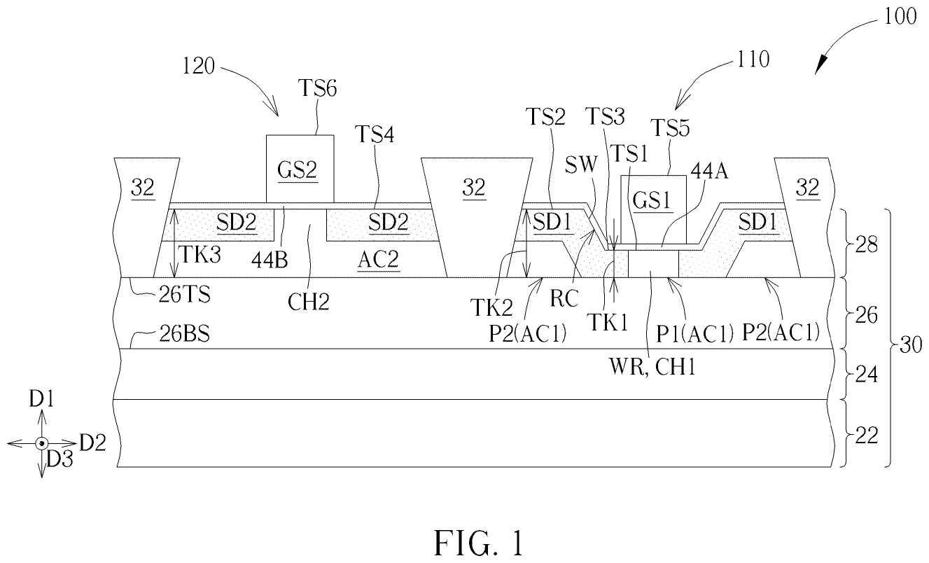

Please refer to FIG. 1. FIG. 1 is a schematic drawing illustrating a semiconductor device 100 according to a first embodiment of the present invention. As shown in FIG. 1, the semiconductor device 100 includes a buried insulation layer 26, a semiconductor layer 28, an isolation structure 32, a recess RC, a first gate structure GS1, and a first source/drain doped region SD1. The semiconductor layer 28 and the isolation structure 32 are disposed on the buried insulation layer 26, and he semiconductor layer 28 includes a first active region AC1 surrounded by the isolation structure 32 in a horizontal direction (such as a horizontal direction D2 and a horizontal direction D3). The recess RC is disposed in the first active region AC1, and the first active region AC1 includes a first portion P1 and a second portion P2. The first portion P1 is located under the recess RC in a vertical direction D1, the second portion P2 is connected with the first portion P1, and a thickness of the second portion P2 (such as a thickness TK2) is greater than a thickness of the first portion P1 (such as a thickness TK1). The first gate structure GS1 is disposed on the first portion P1, the first source/drain doped region SD1 is disposed in the first active region AC1, and the first source/drain doped region SD1 is partly disposed in the second portion P2 and partly disposed in the first portion P1. The thickness of the active region located under the first gate structure GS1 (such as the first portion P1 of the first active region AC1) may be reduced by the formation of the recess RC for improving the operation performance of the device corresponding to the first gate structure GS1 (such as a first device 110). For example, when the first device 110 is a radiofrequency switch device, the figure of merit (FOM) obtained by multiplying the on resistance and the off capacitance may be improved without affecting the breakdown voltage, but not limited thereto. In addition, the first device 110 is not limited to the radiofrequency switch device and may include a low noise amplifier (LNA), a power amplifier (PA), or other suitable devices.

Specifically, in some embodiments, the semiconductor device 100 may further include a substrate 22 and a trap rich layer 24. The buried insulation layer 26 may be disposed on the substrate 22, and the trap rich layer 24 may be disposed between the substrate 22 and the buried insulation layer 26. The substrate 22, the trap rich layer 24, the buried insulation layer 26, and the semiconductor layer 28 may constitute a semiconductor on insulator (SOI) substrate 30, but not limited thereto. The vertical direction D1 described above may be regarded as a thickness direction of the substrate 22 and/or a thickness direction of the buried insulation layer 26. The buried insulation layer 26 may have a top surface 26TS and a bottom surface 26BS opposite to the top surface 26TS in the vertical direction D1. The semiconductor layer 28, the isolation structure 32, and the first gate structure GS1 may be disposed at a side of the top surface 26TS. The trap rich layer 24 and the substrate 22 may be disposed at a side of the bottom surface 26BS. Horizontal directions substantially orthogonal to the vertical direction D1 (such as the horizontal direction D2 and the horizontal direction D3) may be substantially parallel with the top surface 26TS and/or the bottom surface 26BS, but not limited thereto. Additionally, in this description, a distance between the bottom surface 26BS of the buried insulation layer 26 and a relatively higher location and/or a relatively higher part in the vertical direction D1 may be greater than a distance between the bottom surface 26BS of the buried insulation layer 26 and a relatively lower location and/or a relatively lower part in the vertical direction D1. The bottom or a lower portion of each component may be closer to the bottom surface 26BS of the buried insulation layer 26 in the vertical direction D1 than the top or upper portion of this component, but not limited thereto. It is worth noting that, in this description, a top surface of a specific component may include the topmost surface of this component in the vertical direction D1, and a bottom surface of a specific component may include the bottommost surface of this component in the vertical direction D1, but not limited thereto. Additionally, in this description, the condition that a certain component is disposed between two other components in a specific direction may include but is not limited to a condition that the certain component is sandwiched between the two other components in the specific direction.

In some embodiments, the memory device 100 may further include a gate oxide layer 44A and a plurality of the first source/drain doped regions SD1. The gate oxide layer 44A is disposed on the first active region AC1, and the first gate structure GS1 is disposed on the gate oxide layer 44A. The gate oxide layer 44A may be disposed partly in the recess RC and partly outside the recess RC, and the first gate structure GS1 may be disposed in the recess RC and disposed on the gate oxide layer 44A located in the recess RC. In some embodiments, the first gate structure GS1 may substantially extend in the horizontal direction D3, and at least a part of two first source/drain doped regions SD1 may be located at two opposite sides of the first gate structure GS1 in the horizontal direction D2, respectively. In addition, a channel region CH1 may be regarded as a portion of the first active region AC1 located under the first gate structure GS1 and located between the first source/drain doped regions SD1 adjacent to each other, and the channel region CH1 may be disposed in the first portion P1 which is relatively thin in the first active region AC1. A top surface TS1 of the channel region CH1 may be lower than a top surface TS2 of the first source/drain doped region SD1 disposed in the second portion P2 in the vertical direction D1, and a top surface TS3 of the first source/drain doped region SD1 disposed in the first portion P1 may be lower than the top surface TS2 of the first source/drain doped region SD1 disposed in the second portion P2 in the vertical direction D1. In some embodiments, the top surface TS1 and the top surface TS3 may be substantially coplanar, the top surface TS1 and the top surface TS3 may be regarded as a top surface of the first portion P1 of the first active region AC1 also, and the top surface TS2 may be regarded as a top surface of the second portion P2 of the first active region AC1, but not limited thereto.

In some embodiments, because of the influence of the shape of the recess RC, the first active region AC1 may further include a sidewall SW directly connected with the top surface TS2 and the top surface TS3, respectively, and the sidewall SW is a tilted sidewall which is not parallel with the vertical direction D1, but not limited thereto. Therefore, the first portion P1 may include the part of the first active region AC1 located under the sidewall SW in the vertical direction D1, and the thickness TK1 described above may be regarded as the minimum thickness of the first portion P1. In some embodiments, the first source/drain doped region SD1 disposed in the first portion P1 may be directly connected with the first source/drain doped region SD1 disposed in the second portion P2, the minimum thickness of the first source/drain doped region SD1 disposed in the first portion P1 may be substantially equal to the thickness TK1, and the thickness of the first source/drain doped region SD1 disposed in the second portion P2 may be less than the thickness TK2 of the second portion P2, but not limited thereto. In some embodiments, the first device 110 may include the first active region AC1, the first source/drain doped region SD1, the channel region CH1, the gate oxide layer 44A, and the first gate structure GS1, and the semiconductor layer 28 may further include other active regions surrounded by the isolation structure 32 for forming structures different from the first device 110. For example, the semiconductor layer 28 may further include a second active region AC2 surrounded by the isolation structure 32 in the horizontal direction, the second active region AC2 may be separated from the first active region AC1 by the isolation structure 32, and a top surface TS4 of the second active region AC2 may be higher than the top surface of the first portion P1 of the first active region AC1 (such as the top surface TS1 and/or the top surface TS3) in the vertical direction D1.

In some embodiments, the semiconductor device 100 may further include a second gate structure GS2, a gate oxide layer 44B, and a second source/drain doped region SD2. The second gate structure GS2 and the gate oxide layer 44B are disposed on the second active region AC2, and at least a part of the gate oxide layer 44B is located between the second gate structure GS2 and the second active region AC2 in the vertical direction D1. The second source/drain doped region SD2 is disposed in the second active region AC2, a top surface of the second source/drain doped region SD2 (such as a top surface TS4, but not limited thereto) and the top surface TS2 of the first source/drain doped region SD1 disposed in the second portion P2 of the first active region AC1 may be substantially coplanar, and a thickness of the second active region AC2 (such as a thickness TK3) may be substantially equal to the thickness TK2 of the second portion P2 of the first active region AC1, but not limited thereto. In some embodiments, the memory device 100 may include a plurality of the second source/drain doped regions SD2, at least a part of two second source/drain doped regions SD2 may be located at two opposite sides of the second gate structure GS2 in the horizontal direction, respectively, and a channel region CH2 may be regarded as a part of the second active region AC2 located under the second gate structure GS2 and located between the second source/drain doped regions SD2 adjacent to each other. The second gate structure GS2, the gate oxide layer 44B, the second source/drain doped regions SD2, and the second active region AC2 may constitute a second device 120. The second active region AC2 in the second device 120 may have a substantially uniform and consistent thickness for requirements of other devices different from the first device 110. In some embodiments, the first gate structure GS1 and the second gate structure GS2 may be formed concurrently by the same process, and because of the influence of the recess RC, a top surface TS6 of the second gate structure GS2 may be higher than a top surface TS5 of the first gate structure GS1 in the vertical direction D1, but not limited thereto.

In some embodiments, the substrate 22 may include a silicon substrate or a substrate made of other suitable materials. The buried insulation layer 26 may include an oxide insulation layer, such as a buried oxide (BOX) layer, or other suitable insulation materials. The trap rich layer 24 may include undoped polysilicon, silicon oxide, silicon nitride, silicon oxynitride, or other materials with better ability to capture free electrons and different from the material of the substrate 22 and the material of the buried insulation layer 26. The semiconductor layer 28 may include a silicon-containing semiconductor layer (such as a single crystal silicon semiconductor layer) or other kinds of semiconductor materials. The isolation structure 32 may include a single layer or multiple layers of insulation materials, such as an oxide insulation material and an oxynitride insulation material. The first source/drain doped region SD1 and the second source/drain doped region SD2 may respectively include a lightly doped region (not illustrated) and a main doped region (not illustrated) connected with this lightly doped region, and the lightly doped region and the main doped region may be doped regions with N type dopants or P type dopants. The first gate structure GS1 and the second gate structure GS2 may include non-metallic gates, such as polysilicon gates, or gate structures made of other suitable electrically conductive materials, and a spacer (not illustrated) may be disposed on the sidewall of the gate structure according to some design considerations. Additionally, in some embodiments, a doped well region may be formed in the first active region AC1 and/or the second active region AC2 according to some design considerations (such as a well region WR disposed in the first active region AC1), but not limited thereto.

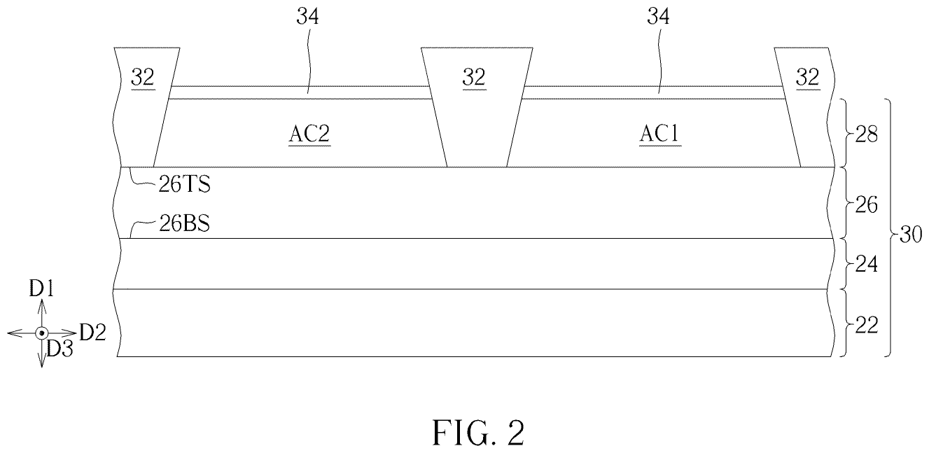

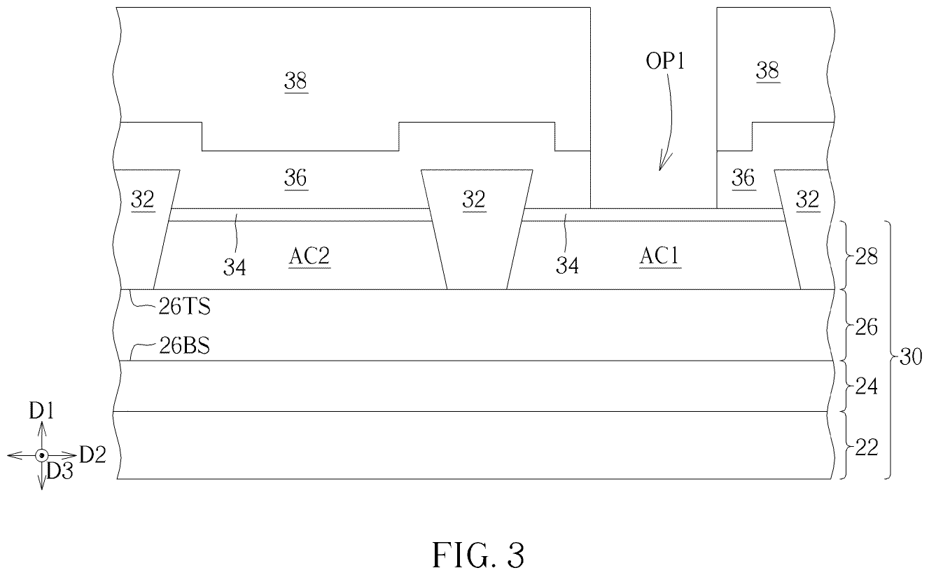

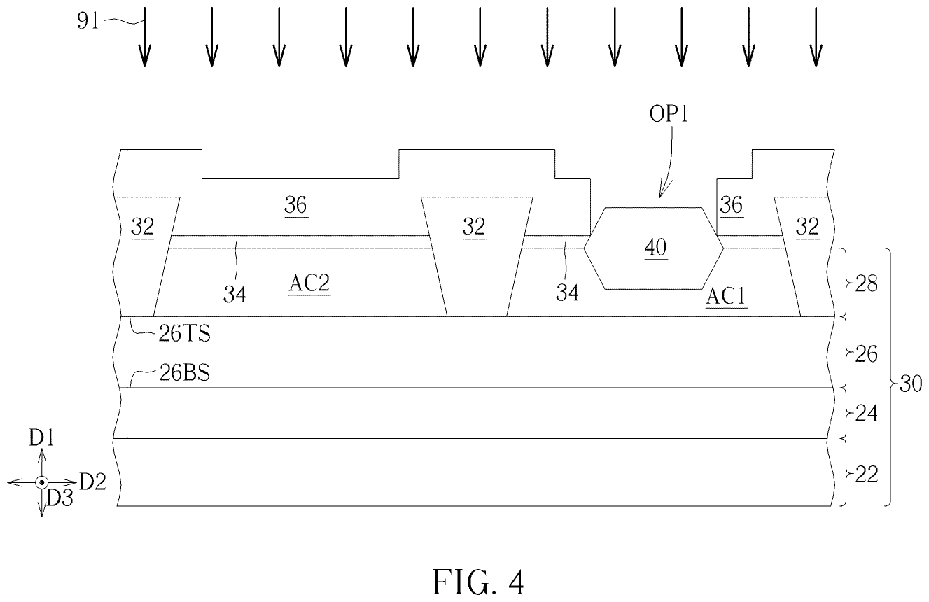

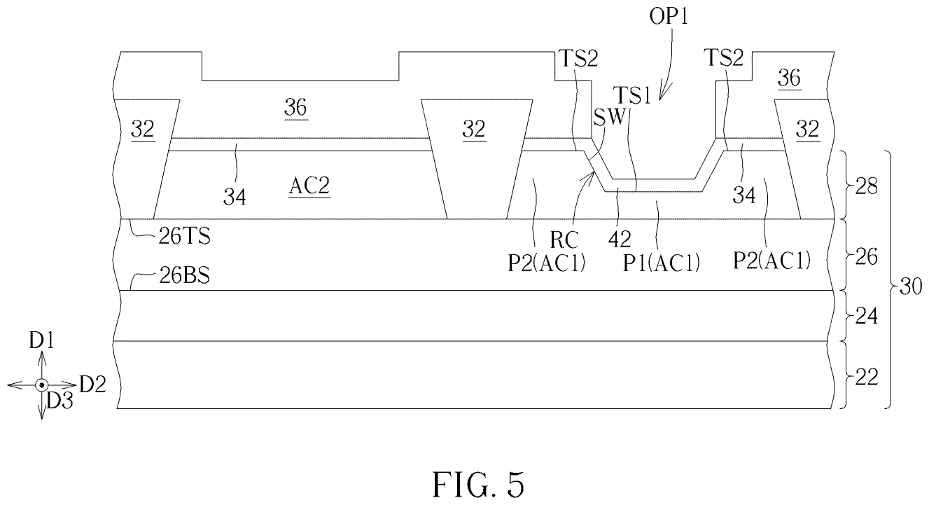

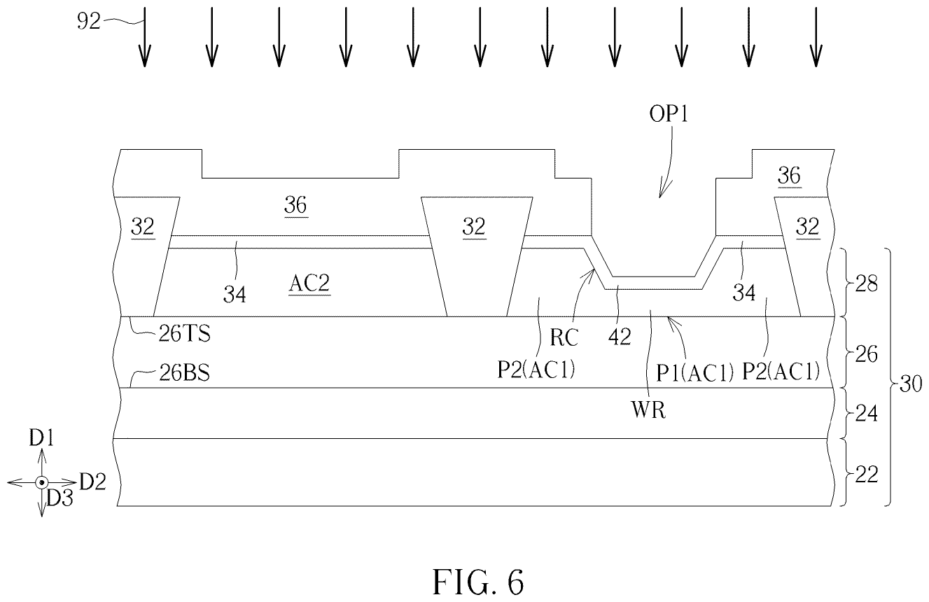

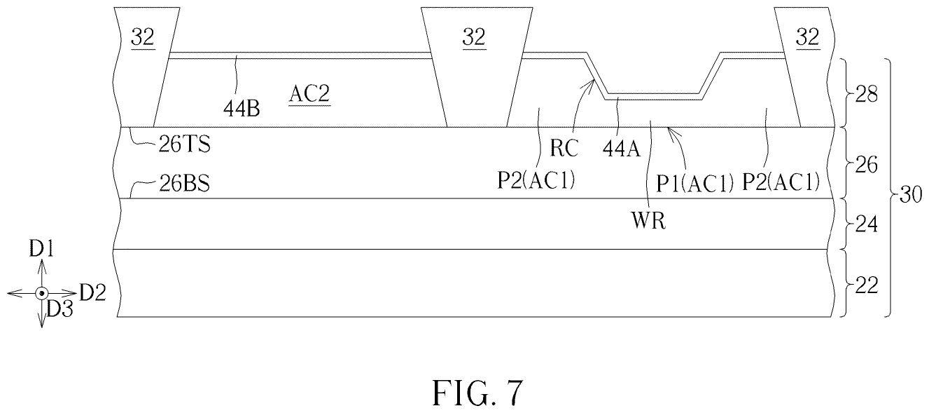

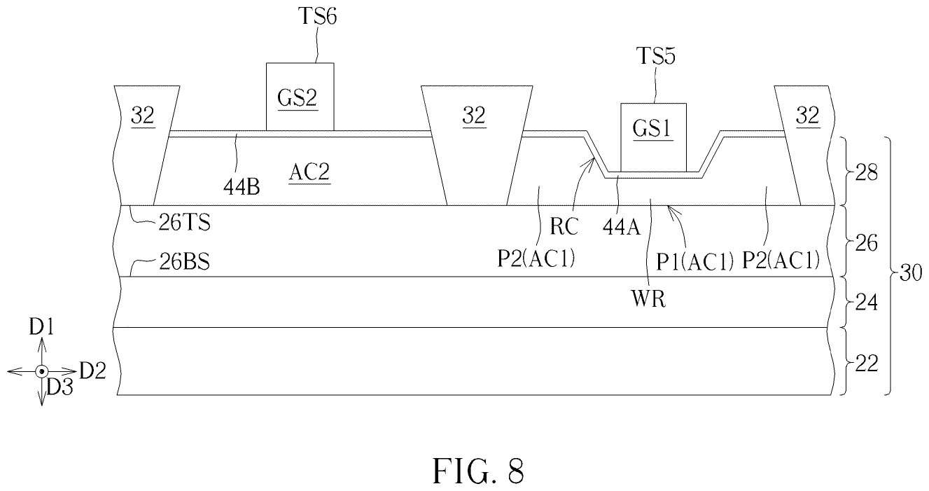

Please refer to FIGS. 1-8. FIGS. 2-8 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 8 is a schematic drawing in a step subsequent to FIG. 7. In some embodiments, FIG. 1 may be regarded as a schematic drawing in a step subsequent to FIG. 8, but not limited thereto. As shown in FIG. 1, the manufacturing method in this embodiment may include the following steps. Firstly, the buried insulation layer 26 is provided, the semiconductor layer 28 and the isolation structure 32 are formed on the buried insulation layer 26, and the semiconductor layer 28 includes the first active region AC1 surrounded by the isolation structure 32. The recess RC is formed in the first active region AC1, and the first active region AC1 includes the first portion P1 and the second portion P2 after the recess RC is formed. The first portion P1 is located under the recess RC, the second portion P2 is connected with the first portion P1, and the thickness of the second portion P2 (such as the thickness TK2) is greater than the thickness of the first portion P1 (such as the thickness TK1). The first gate structure GS1 is formed on the first portion P1, the first source/drain doped region SD1 is formed in the first active region AC1, and the first source/drain doped region SD1 is partly formed in the second portion P2 and partly formed in the first portion P1.

Specifically, the manufacturing method of the semiconductor device in this embodiment may include but is not limited to the following steps. As shown in FIG. 2, in some embodiments, the buried insulation layer 26 may be formed on the trap rich layer 24, the trap rich layer 24 may be formed on the substrate 22, and the semiconductor layer 28 may include the first active region AC1 and the second active region AC2 surrounded and defined by the isolation structure 32. Additionally, in some embodiments, a pad oxide layer 34 may be formed on the semiconductor layer 28 before the isolation structure 32 is formed, and the pad oxide layer 34 may be partly located on the first active region AC1 and partly located on the second active region AC2 after the isolation structure 32 is formed. As shown in FIG. 3, a patterned mask layer 36 may be formed on the semiconductor layer 28, and the patterned mask layer 36 may include an opening OP1 overlapping a part of the first active region AC1. A material of the patterned mask layer 36 may include silicon nitride or other suitable mask materials. In addition, the pad oxide layer 34 is formed before the step of forming the patterned mask layer 36, the patterned mask layer 36 may be formed on the pad oxide layer 34 and the isolation structure 32 accordingly, and the opening OP1 of the patterned mask layer 36 may expose a part of the pad oxide layer 34, such as a part of the pad oxide layer 34 located above the first active region AC1. Additionally, in some embodiments, a mask material layer may be formed on the pad oxide layer 34 and the isolation structure 32, a patterned photoresist layer 38 may be formed on the mask material layer, and an etching process using the patterned photoresist layer 38 as a mask may be performed to the mask material layer for patterning the mask material layer to become the patterned mask layer 36 including the opening OP1, but not limited thereto. In some embodiments, the patterned mask layer 36 including the opening OP1 may also be formed by other approaches according to some considerations.

As shown in FIG. 3 and FIG. 4, the patterned photoresist layer 38 may be removed after the opening OP1 is formed, and an oxidation process 91 may be performed to the first active region AC1 after the patterned photoresist layer 38 is formed for forming an oxide layer 40 in the first active region AC1. A part of the first active region AC1 may be oxidized to become at least a part of the oxide layer 40 by the oxidation process 91. The patterned mask layer 36 including the opening OP1 may be used to control the position where the oxide layer 40 is formed. The first active region AC1 located under the opening OP1 may be partially consumed to become a portion of the oxide layer 40, and the pad oxide layer 34 exposed by the opening OP1 may become another portion of the oxide layer 40, but not limited thereto. In addition, the oxidation process 91 may include a thermal oxidation process or other suitable oxidation approaches. As shown in FIG. 4 and FIG. 5, the oxide layer 40 may be removed for forming the recess RC in the first active region AC1. The recess RC may extend downwards from the top surface of the first active region AC1, and the recess RC may include a tilted sidewall and a relatively flat bottom (such as a portion corresponding to the top surface TS1). After the recess RC is formed, a pad oxide layer 42 may be formed in the recess RC, and the pad oxide layer 42 may be connected with the pad oxide layer 34 located on the first active region AC1. It is worth noting that the method of forming the recess in the present invention may include but is not limited to the steps illustrated in FIGS. 3-5, and the recess RC may also be formed by other suitable approached according to some design considerations.

As shown in FIG. 6, in some embodiments, after the pad oxide layer 42 is formed, a doping process 92 may be performed for forming the well region WR in the first active region AC1, and the area of the well region WR may be adjusted by the process condition of the doping process 92 and is not limited to the portion directly under the opening OP1 in the vertical direction D1. As shown in FIG. 6 and FIG. 7, after the doping process 92, the patterned mask layer 36, the pad oxide layer 34, and the pad oxide layer 42 may be removed, and the gate oxide layer 44A and the gate oxide layer 44B may be formed on the first active region AC1 and the second active region AC2, respectively. Subsequently, as shown in FIG. 8, the first gate structure GS1 and the second gate structure GS2 may be formed on the first active region AC1 and the second active region AC2, respectively. In some embodiments, the first gate structure GS1 and the second gate structure GS2 may be formed concurrently by the same process, and because of the influence of the recess RC, the top surface TS6 of the second gate structure GS2 may be higher than the top surface TS5 of the first gate structure GS1 in the vertical direction D1, but not limited thereto. In addition, as shown in FIGS. 6-8, the patterned mask layer 36, the pad oxide layer 34, and the pad oxide layer 42 may be removed after the recess RC is formed and before the first gate structure GS1 and the second gate structure GS2 are formed, and the gate oxide layer 44A and the gate oxide layer 44B may be formed on the semiconductor layer 28 after the pad oxide layer 34, the pad oxide layer 42, and the patterned mask layer 36 are removed and before the first gate structure GS1 and the second gate structure GS2 are formed. In addition, the first gate structure GS1 and the second gate structure GS2 may be formed on the gate oxide layer 44A and the gate oxide layer 44B, respectively, and the gate oxide layer 44A may be partly formed in the recess RC and partly formed outside the recess RC.

As shown in FIG. 8 and FIG. 1, after the first gate structure GS1 and the second gate structure GS2 are formed, the first source/drain doped region SD1 and the second source/drain doped region SD2 may be formed in the first active region AC1 and the second active region AC2, respectively. In some embodiments, the first source/drain doped region SD1 and the second source/drain doped region SD2 may be formed by the same process or formed by different processes according to some considerations and/or the doping condition. The top surface of the first source/drain doped region SD1 formed in the first portion P1 of the first active region AC1 (such as the top surface TS3) may be lower than the top surface of the first source/drain doped region SD1 formed in the second portion P2 of the first active region AC1 (such as the top surface TS2) in the vertical direction D1, the first source/drain doped region SD1 formed in the first portion P1 may be directly connected with the first source/drain doped region SD1 formed in the second portion P2, and the top surface of the second source/drain doped region SD2 (such as the top surface TS4) and the top surface TS2 of the first source/drain doped region SD1 formed in the second portion P2 may be substantially coplanar, but not limited thereto. Additionally, it is worth noting that the semiconductor device 100 illustrated in FIG. 1 may be formed by the manufacturing method described above, and the manufacturing method in this embodiment may be applied to other embodiments according to some design considerations.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

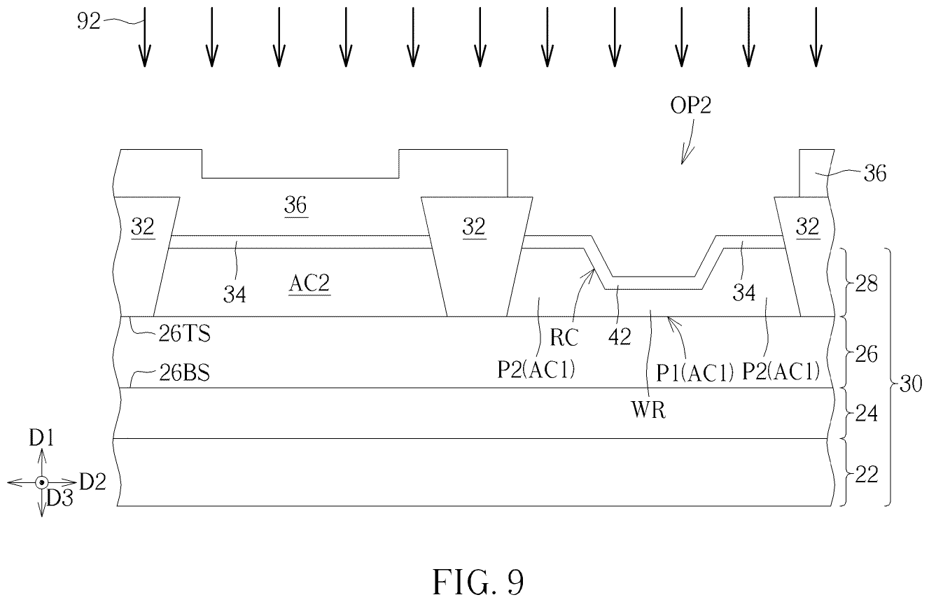

Please refer to FIG. 5 and FIG. 9. FIG. 9 is a schematic drawing illustrating a manufacturing method of a semiconductor device according to another embodiment of the present invention. In some embodiments, FIG. 9 may be regarded as a schematic drawing in a step subsequent to FIG. 5. As shown in FIG. 5 and FIG. 9, in some embodiments, after the recess RC and the pad oxide layer 42 are formed, another patterning process may be performed to the patterned mask layer 36 for expanding the opening OP1 to become an opening OP2. After the opening OP2 is formed, the patterned mask layer 36 may be not located directly above the first active region AC1, and the well region WR formed by the doping process 92 under this situation may be located throughout the first active region AC1. Therefore, in the manufacturing method of this embodiment, an additional photomask and the corresponding photolithographic and etching process may be used to ensure the formation range of the well region WR, and the operation performance of the corresponding device may be enhanced accordingly.

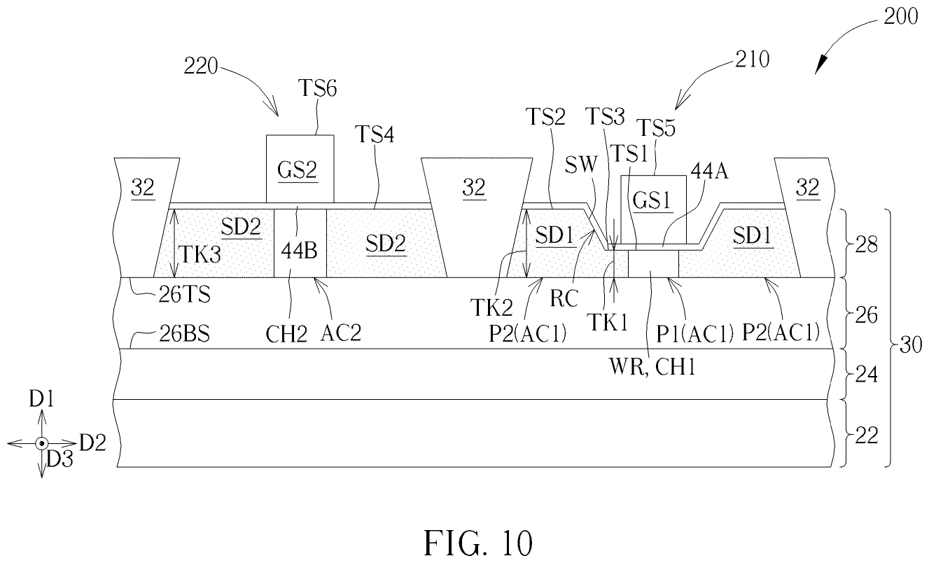

Please refer to FIG. 10. FIG. 10 is a schematic drawing illustrating a semiconductor device 200 according to a second embodiment of the present invention. As shown in FIG. 10, the semiconductor device 200 may include a first device 210 and a second device 220. The first device 210 includes the first active region AC1, the first source/drain doped region SD1, the channel region CH1, the gate oxide layer 44A, and the first gate structure GS1, and the second device 220 may include the second active region AC2, the second source/drain doped region SD2, the channel region CH2, the gate oxide layer 44B, and the second gate structure GS2. In the first device 210, the first source/drain doped region SD1 may be partly disposed in the first portion P1 located under the recess RC and partly disposed in the second portion P2. The thickness of the first source/drain doped region SD1 disposed in the second portion P2 may be substantially equal to the thickness of the second portion P2 (such as the thickness TK2), and the thickness of the first source/drain doped region SD1 disposed in the second portion P2 may be greater than the thickness of the first source/drain doped region SD1 disposed in the first portion P1 (such as the thickness TK1). Additionally, in the second device 220, the thickness of the second source/drain doped region SD2 may be substantially equal to the thickness of the second active region AC2 (such as the thickness TK3), but not limited thereto. In the manufacturing method of the semiconductor device 200, the bottom of the first source/drain doped region SD1 and the bottom of the second source/drain doped region SD2 may extend to the bottom of the first active region AC1 and the bottom of the second active region AC2, respectively, by adjusting the thickness of the semiconductor layer 28 and/or adjusting the process condition of the doping process described above. Because of the influence of the recess RC, the thickness of the first source/drain doped region SD1 formed in the second portion P2 may be greater than the thickness of the first source/drain doped region SD1 formed in the first portion P1. In some embodiments, the first device 210 and the second device 220 may be regarded as fully depleted devices, but not limited thereto.

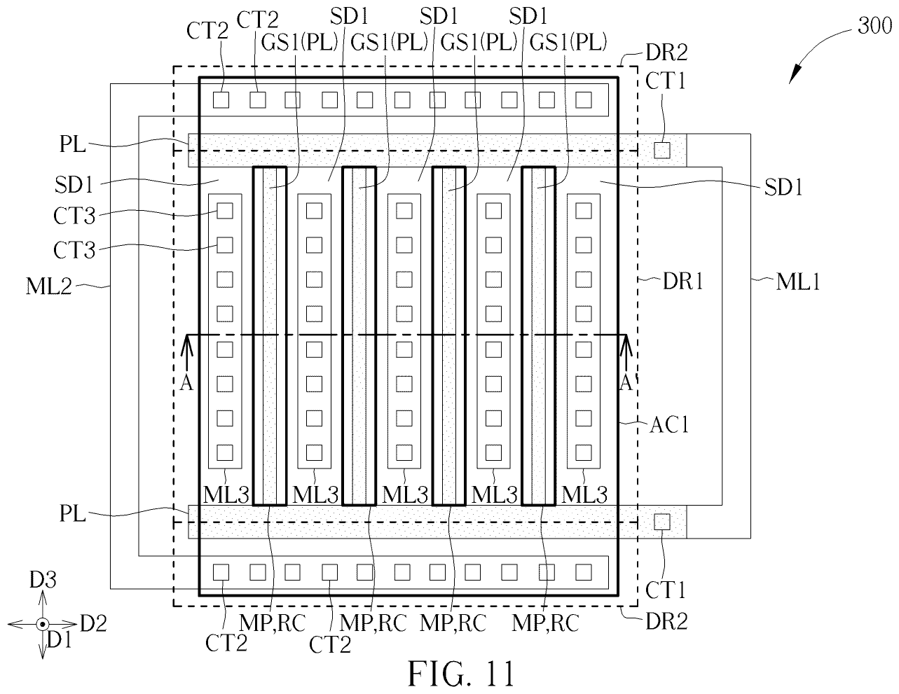

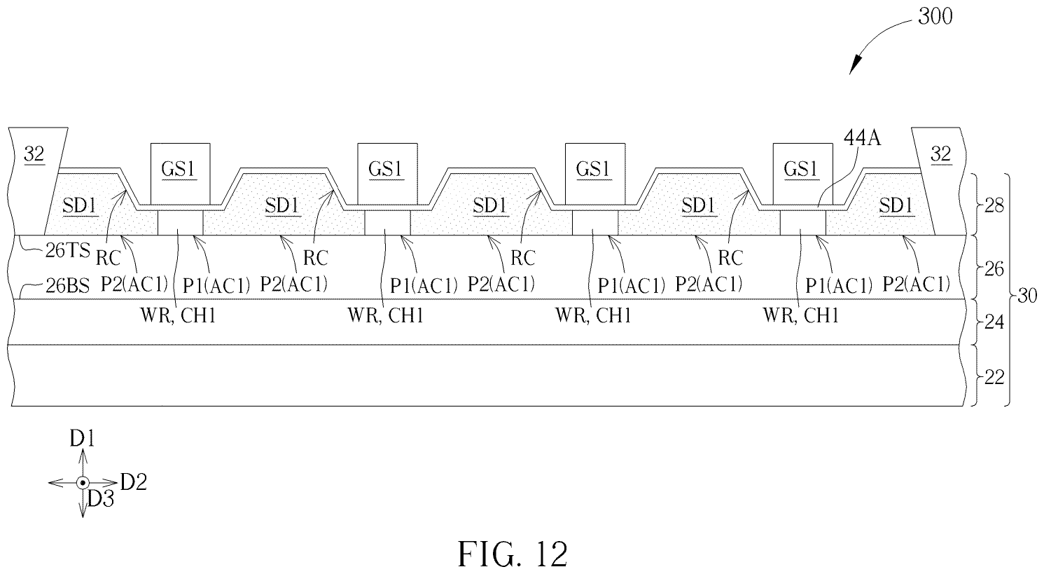

Please refer to FIG. 11 and FIG. 12. FIG. 11 is a schematic drawing illustrating layout design of a semiconductor device 300 according to a third embodiment of the present invention, and FIG. 12 is a schematic drawing illustrating a cross-sectional view of the semiconductor device 300 in this embodiment. In some embodiments, FIG. 12 may be regarded as a partial cross-sectional diagram taken along a line A-A′ in FIG. 11 without illustrating some components (for instance, the electrically conductive pattern ML3 is not illustrated in FIG. 12). As shown in FIG. 11 and FIG. 12, the semiconductor device 300 may include the semiconductor on insulator substrate 30, the isolation structure 32, the gate oxide layer 44A, and a plurality of the recesses RC described above, and the semiconductor device 300 may further include an electrically conductive pattern PL, an electrically conductive pattern ML1, an electrically conductive pattern ML2, electrically conductive patterns ML3, contact structures CT1, contact structures CT2, and contact structures CT3. A part of the electrically conductive pattern PL may be used as the first gate structures GS1 described above, each of the first gate structures GS1 may extend in the horizontal direction D3, and the first gate structures GS1 may be arranged in the horizontal direction D2 substantially orthogonal to the horizontal direction D3. The first gate structures GS1 may be connected with one another via the other portion of the electrically conductive pattern PL (such as the portion extending in the horizontal direction D2), and the electrically conductive pattern PL may include a patterned polysilicon layer or other suitable patterned electrically conductive materials. In some embodiments, the electrically conductive pattern ML1, the electrically conductive pattern ML2, and the electrically conductive pattern ML3 may be separated portions of the same patterned metal layer, and the patterned metal layer is disposed above the electrically conductive pattern PL in the vertical direction D1.

Mask patterns MP in FIG. 11 may be located corresponding to the position where the recesses RC are formed, and the mask patterns MP may be regarded as opening patterns in a photomask used to form the above-mentioned patterned photoresist layer 38 in FIG. 3, but not limited thereto. In addition, a doping range DR1 and a doping range DR2 illustrated in FIG. 11 may be regarded as mask opening ranges for forming different doped regions in the first active region AC1. For example, a plurality of the first source/drain doped regions SD1 may be formed in the first active region AC1 via the doping range DR1 and the corresponding doping process, and a doped region with a conductivity type complementary to that of the first source/drain doped regions SD1 may be formed in the first active region AC1 via the doping range DR2 and the corresponding doping process, but not limited thereto. In addition, the electrically conductive pattern ML1 may be electrically connected with the electrically conductive pattern PL and the first gate structures GS1 in the electrically conductive pattern PL via the contact structures CT1, the electrically conductive pattern ML2 may be electrically connected with the doped region formed by the doping range DR2 via the contact structures CT2, and the electrically conductive patterns ML3 may be electrically connected with the corresponding first source/drain doped regions SD1 via the contact structures CT3. In some embodiments, the semiconductor device 300 may be regarded as a radiofrequency switch device, and the layout design illustrated in FIG. 11 may be regarded as a layout design of the radiofrequency switch device, but not limited thereto. As shown in FIG. 11 and FIG. 12, because of the influence of the recesses RC, the first active region AC1 in this embodiment may include a plurality of the first portions P1, each of the first portions P1 may extend in the horizontal direction D3, and the first portions P1 may be arranged in the horizontal direction D2. Each of the first gate structures GS1 may be disposed in the corresponding recess RC and located on the corresponding first portion P1. In addition, the first source/drain doped region SD1 located between the first gate structures GS1 adjacent to each other in the horizontal direction D2 may be partly disposed in two of the first portions P1 adjacent to each other, and the channel regions CH1 and the first source/drain doped regions SD1 may be alternately arranged in the horizontal direction D2.

To summarize the above descriptions, in the semiconductor device and the manufacturing method thereof according to the present invention, the thickness of the active region located under the gate structure may be reduced by the recess for improving the operation performance of the semiconductor device. For example, the figure of merit (FOM) obtained by multiplying the on resistance (Rₒₙ) and the off capacitance (C_{off}) may be improved without influencing the breakdown voltage relatively, but not limited thereto.

Those skilled in the art will readily observe that numerous modifications and alterations of the device and method may be made while retaining the teachings of the invention. Accordingly, the above disclosure should be construed as limited only by the metes and bounds of the appended claims

What is claimed is:

1. A semiconductor device, comprising:
a buried insulation layer;
a semiconductor layer disposed on the buried insulation layer;
an isolation structure disposed on the buried insulation layer, wherein the semiconductor layer comprises a first active region surrounded by the isolation structure;
a recess disposed in the first active region, wherein the first active region comprises:
a first portion located under the recess; and
a second portion connected with the first portion, wherein a thickness of the second portion is greater than a thickness of the first portion;
a first gate structure disposed on the first portion; and
a first source/drain doped region disposed in the first active region, wherein the first source/drain doped region is partly disposed in the second portion and partly disposed in the first portion.

2. The semiconductor device according to claim 1, wherein a channel region is disposed in the first portion and located under the first gate structure, and a top surface of the channel region is lower than a top surface of the first source/drain doped region disposed in the second portion in a vertical direction.

3. The semiconductor device according to claim 1, wherein a top surface of the first source/drain doped region disposed in the first portion is lower than a top surface of the first source/drain doped region disposed in the second portion in a vertical direction.

4. The semiconductor device according to claim 1, wherein the first source/drain doped region disposed in the first portion is directly connected with the first source/drain doped region disposed in the second portion.

5. The semiconductor device according to claim 1, wherein a thickness of the first source/drain doped region disposed in the second portion is greater than a thickness of the first source/drain doped region disposed in the first portion.

6. The semiconductor device according to claim 1, wherein the semiconductor layer further comprises a second active region surrounded by the isolation structure, the second active region is separated from the first active region by the isolation structure, and a top surface of the second active region is higher than a top surface of the first portion of the first active region in a vertical direction.

7. The semiconductor device according to claim 6, further comprising:
a second gate structure disposed on the second active region, wherein a top surface of the second gate structure is higher than a top surface of the first gate structure in the vertical direction.

8. The semiconductor device according to claim 6, further comprising:
a second source/drain doped region disposed in the second active region, wherein a top surface of the second source/drain doped region and a top surface of the first source/drain doped region disposed in the second portion of the first active region are coplanar.

9. A manufacturing method of a semiconductor device, comprising:
providing a buried insulation layer;
forming a semiconductor layer on the buried insulation layer;
forming an isolation structure on the buried insulation layer, wherein the semiconductor layer comprises a first active region surrounded by the isolation structure;
forming a recess in the first active region, wherein after the recess is formed, the first active region comprises:
a first portion located under the recess; and
a second portion connected with the first portion, wherein a thickness of the second portion is greater than a thickness of the first portion;
forming a first gate structure on the first portion; and
forming a first source/drain doped region in the first active region, wherein the first source/drain doped region is partly formed in the second portion and partly formed in the first portion.

10. The manufacturing method of the semiconductor device according to claim 9, wherein a method of forming the recess comprises:
forming a patterned mask layer on the semiconductor layer, wherein the patterned mask layer comprises an opening overlapping a part of the first active region;
performing an oxidation process to the first active region for forming an oxide layer in the first active region, wherein a part of the first active region is oxidized to become the oxide layer by the oxidation process; and
removing the oxide layer for forming the recess in the first active region.

11. The manufacturing method of the semiconductor device according to claim 10, further comprising:
forming a pad oxide layer on the semiconductor layer before the patterned mask layer is formed, wherein the patterned mask layer is formed on the pad oxide layer, and the opening of the patterned mask layer exposes a part of the pad oxide layer.

12. The manufacturing method of the semiconductor device according to claim 11, further comprising:
removing the pad oxide layer and the patterned mask layer after the recess is formed and before the first gate structure is formed.

13. The manufacturing method of the semiconductor device according to claim 12, further comprising:
forming a gate oxide layer on the semiconductor layer after the pad oxide layer and the patterned mask layer are removed and before the first gate structure is formed, wherein the first gate structure is formed on the gate oxide layer, and the gate oxide layer is partly formed in the recess and partly formed outside the recess.

14. The manufacturing method of the semiconductor device according to claim 9, wherein a channel region is located in the first portion and located under the first gate structure, and a top surface of the channel region is lower than a top surface of the first source/drain doped region formed in the second portion in a vertical direction.

15. The manufacturing method of the semiconductor device according to claim 9, wherein a top surface of the first source/drain doped region formed in the first portion is lower than a top surface of the first source/drain doped region formed in the second portion in a vertical direction.

16. The manufacturing method of the semiconductor device according to claim 9, wherein the first source/drain doped region formed in the first portion is directly connected with the first source/drain doped region formed in the second portion.

17. The manufacturing method of the semiconductor device according to claim 9, wherein a thickness of the first source/drain doped region formed in the second portion is greater than a thickness of the first source/drain doped region formed in the first portion.

18. The manufacturing method of the semiconductor device according to claim 9, wherein the semiconductor layer further comprises a second active region surrounded by the isolation structure, the second active region is separated from the first active region by the isolation structure, and a top surface of the second active region is higher than a top surface of the first portion of the first active region in a vertical direction.

19. The manufacturing method of the semiconductor device according to claim 18, further comprising:
forming a second gate structure on the second active region, wherein a top surface of the second gate structure is higher than a top surface of the first gate structure in the vertical direction.

20. The manufacturing method of the semiconductor device according to claim 18, further comprising:
forming a second source/drain doped region in the second active region, wherein a top surface of the second source/drain doped region and a top surface of the first source/drain doped region formed in the second portion of the first active region are coplanar.
